(19) United States
(12) Patent Application Publication
(10) Pub. No.: US 2017/0163234 A1
(43) Pub. Date: Jun. 8, 2017

(54) FREQUENCY ADJUSTMENT METHOD OF PIEZOELECTRIC RESONATOR AND THE PIEZOELECTRIC RESONATOR

(71) Applicant: NIHON DEMPA KOGYO CO., LTD., Tokyo (JP)

(72) Inventors: Yuya HIRATSUKA, SAITAMA (JP); Noritoshi KIMURA, SAITAMA (JP); Takahiro OHTSUKA, SAITAMA (JP)

(73) Assignee: NIHON DEMPA KOGYO CO., LTD., Tokyo (JP)

(21) Appl. No.: 15/368,675

(22) Filed: Dec. 5, 2016

(30) Foreign Application Priority Data
Dec. 8, 2015 (JP) 2015-239045

(51) Int. Cl. H03H 3/04; H03H 9/09

(52) U.S. Cl. CPC H03H 3/04; H03H 9/09; H03H 2003/0435; H03H 2003/0407

(57) ABSTRACT

A frequency adjustment method is provided for a piezoelectric resonator including a first vibrator, a second vibrator, a third vibrator, and a supporting portion. The second and the third vibrators connect to ends positioned along a vibration direction of a width-longitudinal mode in the first vibrator. The supporting portion is connected to two ends positioned along a vibration direction of the length-longitudinal mode in the first vibrator. The method includes: setting the second vibrator to a first region, a second region, and a third region along the vibration direction of the width-longitudinal mode; setting the third vibrator to a first region, a second region, and a third region along the vibration direction of the width-longitudinal mode; and performing the frequency adjustment by reducing or adding mass of at least one of the first region and the third region in each of the second vibrator and the third vibrator.

### CROSS-REFERENCE TO RELATED APPLICATIONS

This application is based on and claims priority under 35 U.S.C. §119 to Japanese Patent Application No. 2015-239045, filed on Dec. 8, 2015, the entire content of which is incorporated herein by reference.

### TECHNICAL FIELD

This disclosure relates to a frequency adjustment method of a piezoelectric resonator that vibrates by a coupling of two longitudinal modes and the piezoelectric resonator fabricated by the frequency adjustment method.

### DESCRIPTION OF THE RELATED ART

A piezoelectric resonator that vibrates by a coupling of two longitudinal modes, for example, a GT-cut crystal resonator attracts attention because it has possibility to show a temperature characteristic equal to or greater than an AT-cut crystal resonator. Some of the examples are disclosed by, for example, Japanese Unexamined Patent Application Publication No. 58-47313 (hereinafter referred to as Patent Literature 1), Japanese Unexamined Patent Application Publication No. 2015-43483 (hereinafter referred to as Patent Literature 2), and similar literature. Patent Literature 1 discloses a crystal resonator having a structure where a vibration attenuation portion is connected to each of two facing sides of a vibrator with a rectangular planar shape, via bridges (FIGS. 1A to 1C of Patent Literature 1 or similar drawing). Furthermore, Patent Literature 1 discloses a frequency adjustment method that does not cause degradation of a temperature characteristic even when a vibration frequency of a main vibration is adjusted. Specifically, Patent Literature 1 adjusts the frequency by adding weights in total four regions that are located in the proximity of each of the four sides of the rectangular vibrator and in the proximity of the center of each side (FIG. 2 of Patent Literature 1 or similar drawing).

Patent Literature 2 discloses a GT-cut crystal resonator that includes the following: a first vibrator with a rectangular planar shape; a second vibrator that has a rectangular planar shape and is connected to one of two facing sides of the first vibrator; and a third vibrator that has a rectangular planar shape and is connected to the other of the two sides of the first vibrator (FIG. 2 of Patent Literature 2 or similar drawing). In the crystal resonator disclosed in Patent Literature 2, it is described that a crystal resonator that has a favorable frequency versus temperature characteristic and enables reduction of an influence such as an outside impact is obtainable by setting the side ratio or the thickness of the vibrator, a thickness of an excitation electrode, and similar dimension to a predetermined range (in paragraph 40 of Patent Literature 2 or similar paragraph).

### SUMMARY

However, conventionally, a frequency adjustment method that ensures prevention of degradation of a frequency versus temperature characteristic even when performing a frequency adjustment of a piezoelectric resonator that vibrates by a coupling of two longitudinal modes and includes first to third vibrators is not disclosed, to the knowledge of the inventor of the present application.

A need thus exists for a frequency adjustment method of piezoelectric resonator and a piezoelectric resonator which are not susceptible to the drawback mentioned above.

According to an aspect of this disclosure, there is provided a frequency adjustment method for a piezoelectric resonator vibrating by a coupling of a width-longitudinal mode and a length-longitudinal mode. The piezoelectric resonator includes a first vibrator, a second vibrator, a third vibrator, and a supporting portion. The second vibrator connects to one of two ends positioned along a vibration direction of the width-longitudinal mode in the first vibrator. The third vibrator connects to another of the two ends in the first vibrator. The supporting portion is connected to two ends positioned along a vibration direction of the length-longitudinal mode in the first vibrator. The frequency adjustment method includes: setting the second vibrator to a first region, a second region, and a third region from the first vibrator side along the vibration direction of the width-longitudinal mode; setting the third vibrator to a first region, a second region, and a third region from the first vibrator side along the vibration direction of the width-longitudinal mode; and performing the frequency adjustment by reducing or adding mass of at least one of the first region and the third region in each of the second vibrator and the third vibrator.

### BRIEF DESCRIPTION OF THE DRAWINGS

The foregoing and additional features and characteristics of this disclosure will become more apparent from the following detailed description considered with reference to the accompanying drawings, wherein:

FIGS. 1A, 1B, and 1C are explanatory drawings illustrating a shape of a piezoelectric resonator, first to third vibrators, first to third regions and similar according to an embodiment;

FIG. 2 is a drawing describing a frequency versus temperature characteristic of the piezoelectric resonator according to the embodiment;

FIGS. 3A and 3B are explanatory drawings illustrating a frequency adjustment method of a working example and a mask used for the frequency adjustment method;

FIGS. 4A and 4B are explanatory drawings illustrating a frequency adjustment method of a comparative example 1 and a mask used for the frequency adjustment method;

FIGS. 5A and 5B are explanatory drawings illustrating a frequency adjustment method of a comparative example 2 and a mask used for the frequency adjustment method;

FIG. 6 is an explanatory drawing illustrating an effect of the frequency adjustment method of the working example; and

FIGS. 7A and 7B are explanatory drawings illustrating a frequency adjustment method according to another embodiment.

### DETAILED DESCRIPTION

The following describes the embodiments of frequency adjustment methods and piezoelectric resonators according to this disclosure with reference to the attached drawings.

Each drawing used in descriptions are merely illustrated schematically for understanding the disclosure.

In each drawing used in the descriptions, like reference numerals designate corresponding or identical elements, and therefore such elements will not be further elaborated here.

Shapes, dimensions, material, and similar factor described in the following explanations are merely preferable examples within the scope of this disclosure.

Therefore, the disclosure is not limited to only the following embodiments.

### 1. Structure of Piezoelectric Resonator

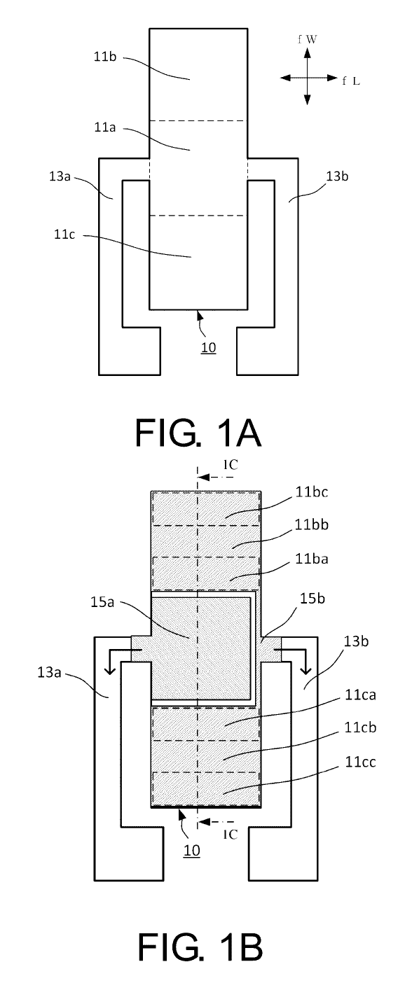

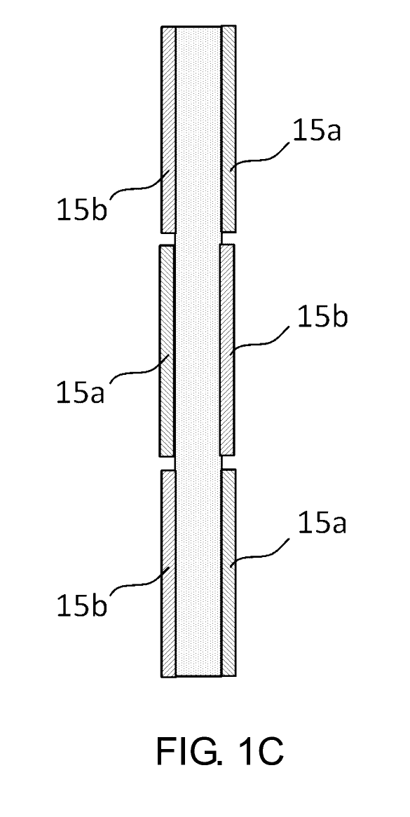

FIGS. 1A to 1C are explanatory drawings illustrating a piezoelectric resonator 10 according to the embodiment. In particular, FIG. 1A is a plan view of a piezoelectric vibrating piece, FIG. 1B is a plan view illustrating a state where excitation electrodes 15a and 15b are disposed on the piezoelectric vibrating piece, and FIG. 1C is a sectional drawing of the piezoelectric resonator 10 taken along the line IC-IC in FIG. 1B. While the piezoelectric resonator 10 is housed in a predetermined container to be sealed in a state of a predetermined atmosphere, a container or similar vessel is omitted in FIGS. 1A, 1B, and 1C and each drawing used in the following descriptions.

The piezoelectric resonator 10 according to the embodiment is a crystal resonator that vibrates by coupling of a width-longitudinal mode and a length-longitudinal mode. Moreover, the piezoelectric resonator 10 includes the following: a first vibrator 11a, a second vibrator 11b, and a third vibrator 11c, where each of them has a rectangular planar shape; supporting portions 13a and 13b; and excitation electrodes 15a and 15b.

Here, the second vibrator 11b connects to one of two ends positioned along the vibration direction of the width-longitudinal mode in the first vibrator 11a (a direction indicated by fW in FIG. 1A). The third vibrator 11c connects to the other of the two ends in the first vibrator 11a. The supporting portions 13a and 13b connect to the two ends positioned along the vibration direction of the length-longitudinal mode in the first vibrator 11a (a direction indicated by fL in FIG. 1A).

One electrode 15a of the excitation electrodes is arranged in one principal surface of the first to third vibrators 11a to 11c, and the other electrode 15b of the excitation electrodes is arranged in the other principal surface of the first to third vibrators 11a to 11c. However, these excitation electrodes 15a and 15b are disposed in the front and back surfaces of the first to third vibrators 11a to 11c such that the polarity of the excitation electrodes in the front and back surfaces of the second vibrator 11b and the third vibrator 11c is reversed with respect to the polarity of the excitation electrodes in the front and back surfaces of the first vibrator 11a (see FIG. 1C). These excitation electrodes 15a and 15b are connected to an external circuit after wired on the supporting portions 13a and 13b (not illustrated).

This embodiment employs a crystal element that causes, what is called, a Y-cut plate of a crystal to rotate by 51.5 degrees around the X-axis of the crystal and causes the plate to further rotate by 45.0 degrees inside the surface and has a thickness of 40 μm; however, it is not limited to this. The dimension in fW direction of the first to third vibrators 11a to 11c is set to approximately 0.81 mm, and the dimension in fL direction of the first to third vibrators 11a to 11c is set to approximately 0.86 mm.

In the piezoelectric resonator 10, the second vibrator 11b is divided to be defined as a first region 11ba, a second region 11bb, and a third region 11bc from the first vibrator 11a side along the vibration direction fW of the width-longitudinal mode. Further, the third vibrator 11c is divided to be defined as a first region 11ca, a second region 116, and a third region 11cc from the first vibrator 11a side along the vibration direction fW of the width-longitudinal mode. Then, these first to third regions are, in this embodiment, regions where the vibrator, to which these regions belong, is divided into approximately three equal parts along fW direction. Consequently, when the dimension of each vibrator in fW direction is 0.81 mm as illustrated above, the dimension of each of the first to third regions 11ba, 11ca, 11bb, 11cb, 11bc, 11cc in fW direction is approximately 0.27 mm.

### 2. Experiment

Next, an experiment was performed with the following procedures of a to d with respect to the piezoelectric resonator 10 illustrated in FIGS. 1A to 1C to specify a preferred frequency adjustment method for this piezoelectric resonator 10.

a. Before performance of a frequency adjustment, a frequency versus temperature characteristic relative to an environmental temperature of the piezoelectric resonator 10 was measured.

b. Next, the frequency adjustment of the piezoelectric resonator 10 was performed with three conditions of a working sample, a comparative example 1, and a comparative example 2, which are described below.

c. Next, the frequency versus temperature characteristic was measured again.

d. By comparing the temperature characteristic before and after the frequency adjustment, the frequency adjustment method that caused smaller-degree degradation of temperature characteristic even when the frequency adjustment was performed, namely, the preferred frequency adjustment method was identified.

### 2-1. Description of Frequency Versus Temperature Characteristic

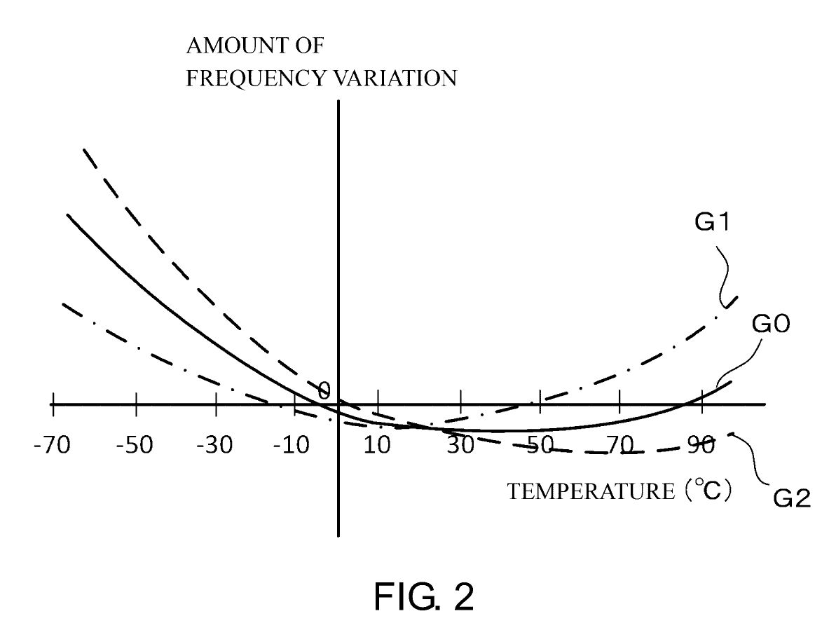

First, the frequency versus temperature characteristic of the piezoelectric resonator 10 will be described. The frequency versus temperature characteristic is expressed by the following formula (1) or formula (2). However, an influence of the third-order term in the formula (2) relative to the frequency versus temperature characteristic is small, and focusing on the second-order and first-order terms is effective for evaluation. Thus, the experiment was performed by approximation with the formula (1). Consequently, the frequency versus temperature characteristic before and after the frequency adjustment in this experiment is describable with the schematic diagram illustrated in FIG. 2. That is, the frequency versus temperature characteristic before the frequency adjustment of the piezoelectric resonator 10 is, for example, the quadratic curve indicated by G0 in FIG. 2, and the frequency versus temperature characteristic after the frequency adjustment of the piezoelectric resonator 10 is the quadratic curve indicated by G1 or G2 in FIG. 2. The meaning of G1 and G2 indicates that in some cases a variation direction of the frequency versus temperature characteristic varies according to the frequency adjustment. Consequently, the smaller the difference between G0 and G1 (G2) is, the more preferable the frequency adjustment method is. Obviously, G0=G1 or G0=G2 is the most preferable. In FIG. 2, the vertical axis indicates an amount of frequency variation (ppm), and the horizontal axis indicates a temperature (° C.).

Δf=β(t−to)(t−to)+α(t−to)+C (1)

Δf=γ(t−to)(t−to)(t−to)+β(t−to)(t−to)+α(t−to)+C (2)

Here, in the formula (1) and the formula (2), α, β, and γ are coefficients, C is a constant, t is an environmental temperature, and to is any reference temperature.

### 2-2. Detail of Experiment

Next, the detail of the experiment will be described.

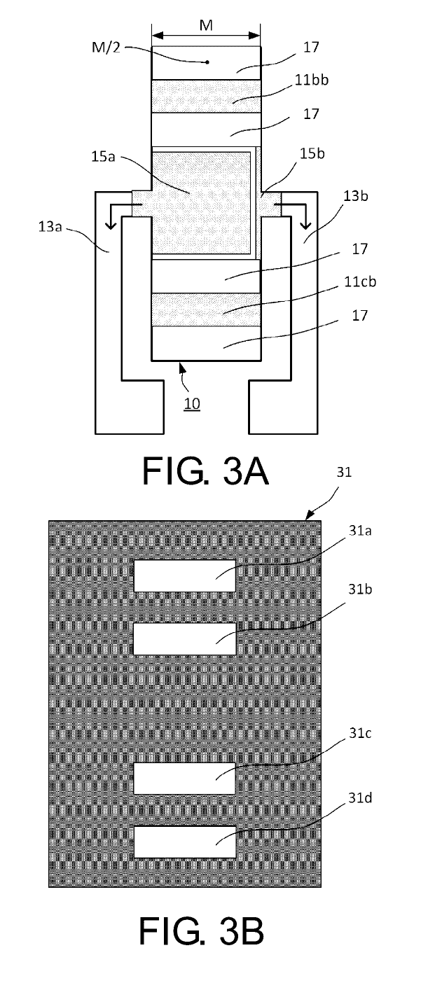

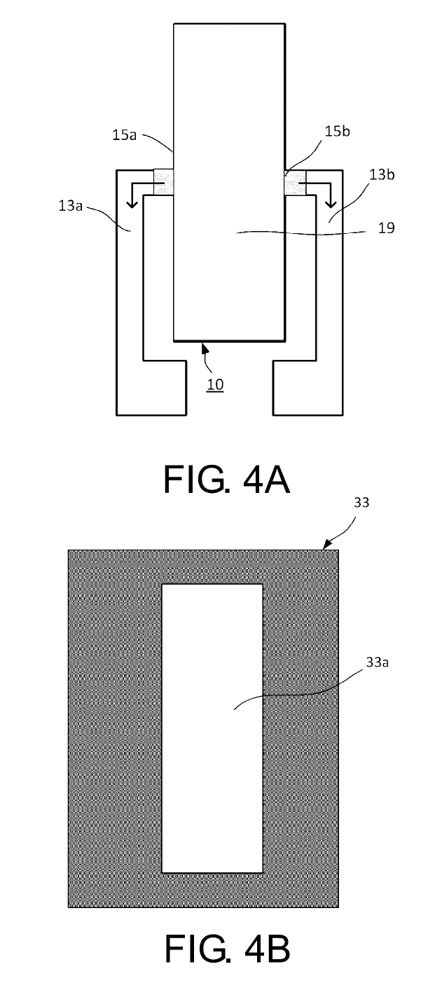

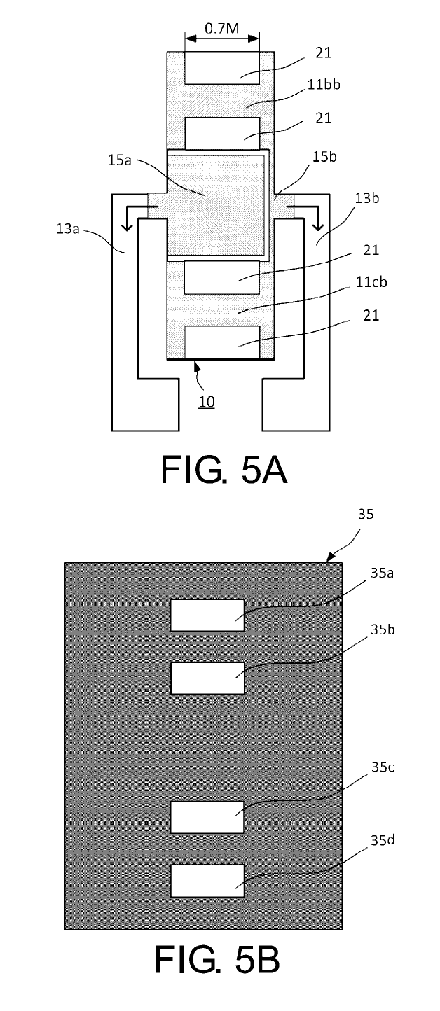

FIGS. 3A and 3B are the drawings illustrating the experimental condition of the working example; FIGS. 4A and 4B are the drawings illustrating the experimental condition of the comparative example 1; and FIGS. 5A and 5B are the drawings illustrating the experimental condition of the comparative example 2. In any of those drawings, FIGS. 3A, 4A, and 5A are plan views mainly illustrating frequency adjustment regions of the piezoelectric resonator 10, and FIGS. 3B, 4B, and 5B are drawings illustrating masks used for the frequency adjustment.

### Working Example

First, in the working example, the first region 11ba and the third region 11bc of the second vibrator 11b, and the first region 11ca and the third region 11cc of the third vibrator 11c, which are illustrated in FIGS. 1A, 1B, and 1C, were removed by a predetermined amount with an ion milling method. Specifically, a mask 31 having openings 31a to 31d illustrated in FIG. 3B was superimposed on the piezoelectric resonator 10, and then the portions that are exposed from the openings 31a to 31d of the excitation electrodes 15a and 15b were removed by the predetermined amount. In this experiment, the frequency adjustment was performed with two conditions as follows: the condition where the frequency of the width-longitudinal-mode vibration (main vibration) of the piezoelectric resonator 10 varies by approximately 1,000 ppm; and the condition where the frequency of the main vibration varies by approximately 2,000 ppm. Three samples were used in the experiment.

Varying the frequency of the main vibration varies the frequency of the length-longitudinal-mode vibration (an unwanted response), and thus the frequency of the length-longitudinal-mode vibration was also measured. The amounts of frequency variation of the main vibration and the unwanted response are described in the column of ΔfW and the column of ΔfL in table 1, which is described later, respectively.

In FIG. 3A, the region where the excitation electrode was removed in the above-described frequency adjustment, namely, a mass-reduction mark 17 is indicated. Then, assuming that the dimension along the vibration direction of the length-longitudinal mode in the first region and the third region is M (see FIGS. 3A and 3B), the mass-reduction marks 17 in the working example are caused in the regions that have a dimension of M centered at the positions of M/2 (see FIGS. 3A and 3B) in the first and third regions. That is, in this working example, the whole region of the first and third regions is the mass-reduction mark.

### Comparative Example 1

In the comparative example 1, the whole region of the first to third vibrators 11a to 11c, which are illustrated in FIGS. 1A to 1C, is removed by a predetermined amount by the ion milling method.

Specifically, as illustrated in FIG. 4B, a mask 33 having an opening 33a that corresponds to the whole region of the first to third vibrators is superimposed on the piezoelectric resonator 10, and then the portion exposed from the opening 33a of the excitation electrodes 15a and 15b is removed by the predetermined amount. In this experiment, similar to the working example, the frequency adjustment was performed with two conditions as follows: the condition where the frequency of the width-longitudinal-mode vibration (main vibration) of the piezoelectric resonator 10 varies by approximately 1,000 ppm; and the condition where the frequency of the main vibration varies by approximately 2,000 ppm. Similar to the working example, three samples were used in the experiment. At that time, the frequency of the unwanted response was measured. The amounts of frequency variation of the main vibration and the unwanted response are described in the column of ΔfW and the column of ΔfL in table 1, respectively.

In FIG. 4A, a region 19 where the excitation electrode is removed in the above-described frequency adjustment is indicated. However, since the excitation electrode of the first vibrator was also removed, and the excitation electrodes of the second region in each of the first and second vibrators were also removed, the comparative example 1 falls outside the scope of this disclosure.

### Comparative Example 2

In the comparative example 2, a part (a portion of 70% described later) of the first region 11ba and the third region 11bc in the second vibrator 11b and a part (a portion of 70% described later) of the first region 11ca and the third region 11cc in the third vibrator 11c, which are illustrated in FIGS. 1A to 1C, is removed by a predetermined amount with the ion milling method. Specifically, a mask 35 having openings 35a to 35d illustrated in FIG. 5B was superimposed on the piezoelectric resonator 10, and then the portions exposed from the openings 35a to 35d of the excitation electrodes 15a and 15b are removed by the predetermined amount. In this experiment, similar to the working example, the frequency adjustment was performed with two conditions as follows: the condition where the frequency of the width-longitudinal-mode vibration (main vibration) of the piezoelectric resonator 10 varies by approximately 1,000 ppm; and the condition where the frequency of the main vibration varies by approximately 2,000 ppm. Similar to the working example, three samples were used in the experiment. At that time, the frequency of the unwanted response was measured. The amounts of frequency variation of the main vibration and the unwanted response are described in the column of ΔfW and the column of ΔfL in table 1, respectively.

In FIG. 5A, a region where the excitation electrode was removed in the above-described frequency adjustment, namely, a mass-reduction mark 21 is indicated. Then, assuming that the dimension along the vibration direction of the length-longitudinal mode in the first region and the third region is M (see FIGS. 3A and 3B), the mass-reduction marks 21 in the comparative example 2 are caused in the regions that have a dimension of 0.7M centered at the positions of M/2 (see FIGS. 3A and 3B) in the first and third regions. That is, in the comparative example 2, the portions having a width of 70% with respect to the dimension M in the width direction in the first and third regions in FIGS. 5A and 5B is the mass-reduction mark.

### 2-3. Summary and Examination of Experimental Result

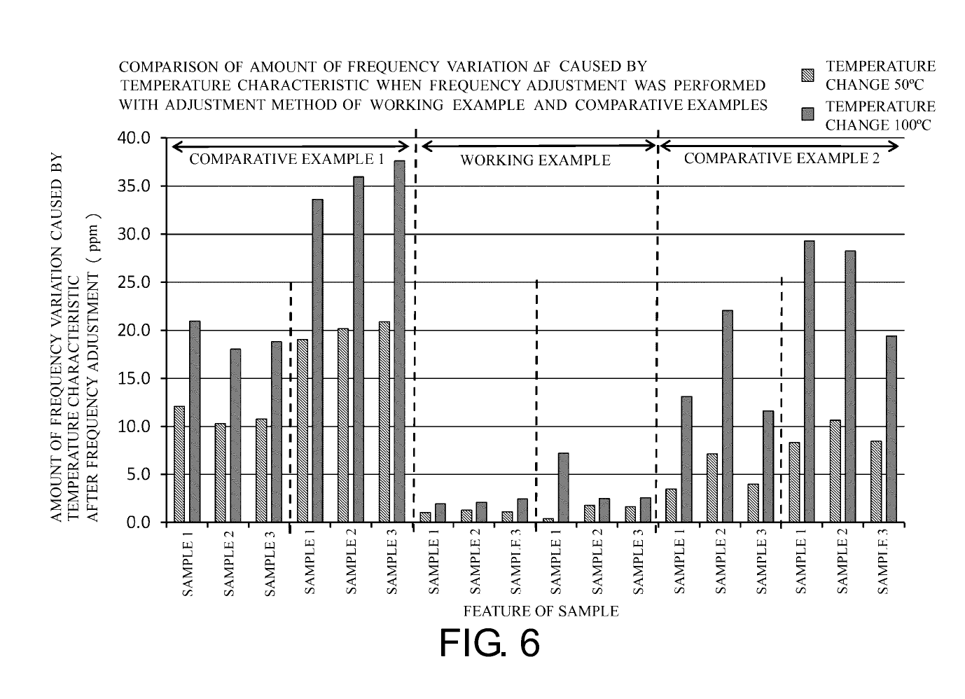

Summary and examination will be described with reference to Tables 1 to 3 and FIG. 6.

Table 1 summarizes the coefficients α and β of the approximation formula of the frequency versus temperature characteristic, variation amounts Δα and Δβ of the coefficients, and the variation amounts ΔfW and ΔfL of the main vibration and the unwanted response, before and after the adjustment, when the frequency of the piezoelectric resonator 10 was adjusted with each experimental condition of the above-described working example, comparative example 1, and comparative example 2.

Table 2 summarizes and indicates the amounts of frequency variation caused by the differences of the temperature characteristic before and after the frequency adjustment of the piezoelectric resonator 10 for each of the working example, the comparative example 1, and the comparative example 2. Specifically, the absolute values of the differences between β (t−to) (t−to) and α (t−to) in the approximation formula (1) when the temperature change is 50° C., for the working example, the comparative example 1, and the comparative example 2, are summarized and indicated. The column of ΔF in Table 2 indicates the absolute values of the differences between β (t−to) (t−to) and α (t−to). The smaller ΔF means the smaller degradation of the temperature characteristic caused by the frequency adjustment.

Table 3 summarizes and indicates the absolute values of the differences between β (t−to) (t−to) and α (t−to) when the temperature change is 100° C., for the working example, the comparative example 1, and the comparative example 2. This is indicated for verification in addition to the case where the temperature change is 50° C.

FIG. 6 is a graph to compare the values of ΔF indicated in Table 2 and Table 3 for the working example, the comparative example 1, and the comparative example 2. The graph in FIG. 6 indicates that the frequency adjustment method of the working example ensures preventing the degradation of the frequency versus temperature characteristic when the frequency adjustment is performed, compared with the comparative example 1 and the comparative example 2. That is, it is seen that the amount of frequency variation in the method of the working example is less than 8 ppm in both frequency-adjustment amounts of 1,000 ppm and 2,000 ppm, and thus the method of the working example is superior to the comparative examples.

In the comparative example 2, as illustrated in FIG. 5A, the mass-reduction marks of the first and third regions have a dimension of 0.7M centered at the center point M/2 (see FIGS. 3A and 3B), relative to the dimension M in the first and third regions. The poorest result of the amount of frequency variation ΔF in the comparative example 2 is approximately 30 ppm in the sample 1 with the frequency-adjustment amount 2,000 ppm. In the working example, as illustrated in FIG. 3A, the mass-reduction marks of the first and third regions have an identical dimension of M centered at the center point M/2 (see FIGS. 3A and 3B), relative to the dimension M in the first and third regions. The poorest result of the amount of frequency variation ΔF in the working example is approximately 8 ppm in the sample 1 with the frequency-adjustment amount 2,000 ppm. Even when the sample of 8 ppm is considered to be an experimental error, it is possible to reduce the amount of frequency variation in the working example equal to or less than 10 ppm, in detail, equal to or less than 8 ppm.

Therefore, it is seen that the frequency adjustment method of this disclosure ensures to reduce the degradation of the frequency versus temperature characteristic caused by the frequency adjustment, and thus is a preferred frequency adjustment method. It is seen that the mass-reduction mark is more preferable to extend toward the dimension M by exceeding the dimension 0.7M, centered at the center point M/2 (see FIGS. 3A and 3B), relative to the above-described dimension M.

Examining the column of Δα in Table 1 by changing an aspect indicates that while the values of Δα are positive values in the comparative example 1 and the working example, they are negative values in the comparative example 2. In the working example and the comparative example 2, the values of Δα are close to zero, compared with the comparative example 1. In particular, in the working example, the values of Δα are the positive values in addition to the values close to zero. By considering that the values of Δβ in Table 1 indicate the negative values in all conditions, the condition of the working example, where the values of Δα indicate the positive value, means that it has components cancelling Δβ, and the frequency variation in Δα itself is small. Therefore, from this point as well, it is seen that the adjustment method of the working example has an advantage compared with the comparative examples.

Furthermore, as another aspect, a ratio ΔfL/ΔfW between the amount of frequency variation MW of the main vibration and the amount of frequency variation MI of the unwanted response in Table 1 will be examined. ΔfL/ΔfW is in a range of 0.94 to 1.04 in the comparative example 1, is in a range of 0.61 to 0.74 in the working example, and is in a range of 0.08 to 0.14 in the comparative example 2. This indicates that, in the frequency adjustment method of this disclosure, a frequency adjustment region is selected such that ΔfL/ΔfW, which is the ratio of the amount of frequency variation of the unwanted response to the amount of frequency variation of the main vibration, becomes 0.6≦ΔfL/ΔfW≦0.75. Considering conversely, selecting the frequency adjustment region such that ΔfL/ΔfW becomes 0.6≦ΔfL/ΔfW≦0.75 also ensures that the reduced degradation of the frequency versus temperature characteristic caused by the frequency adjustment.

### 3. Modification

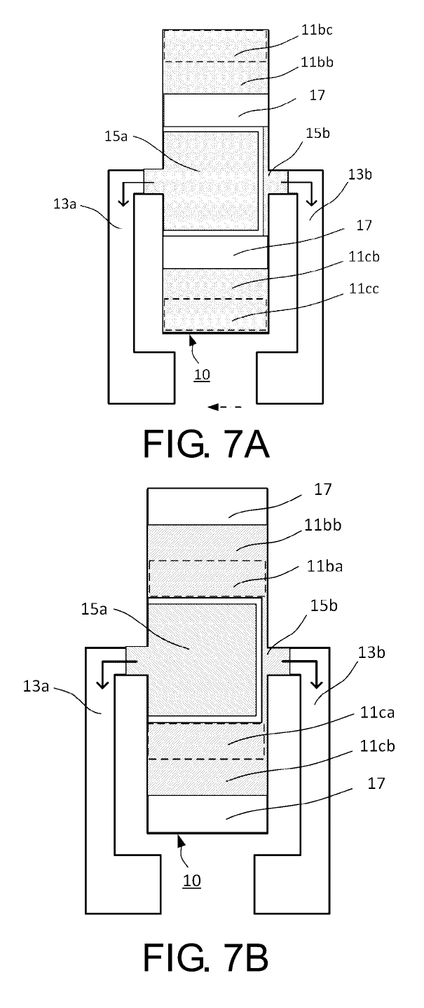

In the above description, the embodiments of the frequency adjustment method of this disclosure have been described; however, this disclosure is not limited to the above-described embodiments. For example, in the above-described examples, the examples that adjusted the first regions and the third regions of the second vibrator and the third vibrator have been described; however, as illustrated in FIG. 7A, only the first region in each of the second vibrator and the third vibrator may be set as the frequency adjustment region (mass-reduction mark) 17. Further, as illustrated in FIG. 7B, only the third region in each of the second vibrator and the third vibrator may be set as the frequency adjustment region (mass-reduction mark) 17.

Furthermore, in the above-described embodiments, the first to third vibrators have the rectangular planar shape; however, this disclosure is applicable even when they have approximately rectangular planar shape with a curved corner portion, a circular planar shape, or an elliptical planar shape.

Further, in the above-described embodiments, the examples that removed the excitation-electrode portions, which correspond to the frequency adjustment regions, with the ion milling method have been described; however, contrary to this, a method that adds mass may be employed. That is, when the original frequency of the piezoelectric resonator 10 is higher than a target frequency, the frequency may be lowered by adding mass to adjust the frequency to the target frequency. A concrete example of such method includes a method that causes a metal film to be deposited on a frequency adjustment region with a vacuum evaporation method or similar method.

TABLE 1
Description of variation of approximation formula of frequency versus temperature characteristic and variation
of main variation fW and unwanted response fL before and after frequency adjustment

| | | Coefficients of approximation formula of | | | | Amount of coefficient | | Amount | | |
|---|---|---|---|---|---|---|---|---|---|---|
| | | frequency versus temperature characteristic | | | | variation before and | | of | | |
| | | Before frequency | | After frequency | | after frequency | | frequency | | |
| | | adjustment | | adjustment | | adjustment | | variation | | |
| | | α ppm/ | β ppm/ | α ppm/ | β ppm/ | Δ α ppm/ | Δ β ppm/ | Δ fW | Δ fL | Δ fL/ |
| | | deg C. | deg C.² | deg C. | deg C.² | deg C. | deg C.² | ppm | ppm | Δ fW |
| Comparative Example 1 | Sample 1 | −0.67 | 0.0072 | −0.40 | 0.0066 | 0.27 | −0.00064 | 1013 | 1006 | 0.99 |
| (Amount of frequency | Sample 2 | −0.85 | 0.0057 | −0.62 | 0.0052 | 0.23 | −0.00051 | 1013 | 1054 | 1.04 |
| adjustment 1,000 ppm) | Sample 3 | −0.74 | 0.0064 | −0.49 | 0.0058 | 0.24 | −0.00055 | 1011 | 1062 | 1.05 |
| Comparative Example 1 | Sample 1 | −0.53 | 0.0069 | −0.10 | 0.0060 | 0.43 | −0.00089 | 2030 | 1903 | 0.94 |
| (Amount of frequency | Sample 2 | −1.01 | 0.0057 | −0.56 | 0.0049 | 0.45 | −0.00088 | 2004 | 1902 | 0.95 |
| adjustment 2,000 ppm) | Sample 3 | −0.52 | 0.0070 | −0.06 | 0.0062 | 0.46 | −0.00083 | 2023 | 1926 | 0.95 |
| Working Example | Sample 1 | −0.71 | 0.0064 | −0.64 | 0.0056 | 0.06 | −0.00081 | 1007 | 720 | 0.71 |
| (Amount of frequency | Sample 2 | −0.46 | 0.0069 | −0.39 | 0.0060 | 0.07 | −0.00093 | 1010 | 744 | 0.74 |
| adjustment 1,000 ppm) | Sample 3 | −0.70 | 0.0063 | −0.63 | 0.0054 | 0.07 | −0.00094 | 1011 | 749 | 0.74 |
| Working Example | Sample 1 | −0.81 | 0.0059 | −0.73 | 0.0043 | 0.09 | −0.00160 | 2017 | 1236 | 0.61 |
| (Amount of frequency | Sample 2 | −0.32 | 0.0074 | −0.22 | 0.0062 | 0.10 | −0.00122 | 2010 | 1195 | 0.59 |
| adjustment 2,000 ppm) | Sample 3 | −0.83 | 0.0063 | −0.73 | 0.0051 | 0.09 | −0.00117 | 2025 | 1285 | 0.63 |
| Comparative Example 2 | Sample 1 | 1.64 | 0.0129 | 1.63 | 0.0117 | −0.01 | −0.00123 | 1013 | 79 | 0.08 |
| (Amount of frequency | Sample 2 | 2.05 | 0.0100 | 1.98 | 0.0085 | −0.07 | −0.00155 | 1005 | 87 | 0.09 |
| adjustment 1,000 ppm) | Sample 3 | 1.79 | 0.0128 | 1.75 | 0.0121 | −0.04 | −0.00073 | 1005 | 91 | 0.09 |
| Comparative Example 2 | Sample 1 | 3.34 | 0.0171 | 3.30 | 0.0146 | −0.04 | −0.00254 | 2009 | 331 | 0.16 |
| (Amount of frequency | Sample 2 | 3.41 | 0.0166 | 3.26 | 0.0152 | −0.14 | −0.00139 | 1998 | 253 | 0.13 |
| adjustment 2,000 ppm) | Sample 3 | 3.11 | 0.0159 | 2.97 | 0.0154 | −0.14 | −0.00050 | 2001 | 276 | 0.14 |

TABLE 2
Amount of frequency variation ΔF when a certain
temperature variation occurs, in variation of
coefficients Δα and Δβ indicated in Table 1
(In temperature change of 50° C.)

| | | Amount of frequency variation in | | |
|---|---|---|---|---|
| | | temperature change of 50° C. (ppm) | | |
| | | Amount of | Amount of | |
| | | frequency | frequency | |
| | | variation by | variation by | |
| | | Δα = | Δβ = | |
| | | Δα*50 | Δβ*50*50 | ΔF |
| Comparative | Sample 1 | 13.7 | −1.6 | 12.1 |
| Example 1 | Sample 2 | 11.6 | −1.3 | 10.3 |
| (Amount of frequency | Sample 3 | 12.2 | −1.4 | 10.8 |
| adjustment 1,000 ppm) | | | | |
| Comparative | Sample 1 | 21.3 | −2.2 | 19.1 |
| Example 1 | Sample 2 | 22.4 | −2.2 | 20.2 |
| (Amount of frequency | Sample 3 | 23.0 | −2.1 | 20.9 |
| adjustment 2,000 ppm) | | | | |
| Working Example | Sample 1 | 3.1 | −2.0 | 1.1 |
| (Amount of frequency | Sample 2 | 3.6 | −2.3 | 1.3 |
| adjustment 1,000 ppm) | Sample 3 | 3.5 | −2.4 | 1.1 |
| Working Example | Sample 1 | 4.4 | −4.0 | 0.4 |
| (Amount of frequency | Sample 2 | 4.8 | −3.0 | 1.8 |
| adjustment 2,000 ppm) | Sample 3 | 4.6 | −2.9 | 1.6 |
| Comparative | Sample 1 | −0.4 | −3.1 | 3.5 |
| Example 2 | Sample 2 | −3.3 | −3.9 | 7.1 |
| (Amount of frequency | Sample 3 | −2.2 | −1.8 | 4.0 |
| adjustment 1,000 ppm) | | | | |
| Comparative | Sample 1 | −2.0 | −6.4 | 8.3 |
| Example 2 | Sample 2 | −7.2 | −3.5 | 10.6 |
| (Amount of frequency | Sample 3 | −7.2 | −1.2 | 8.5 |
| adjustment 2,000 ppm) | | | | |

TABLE 3
Amount of frequency variation ΔF when a certain
temperature variation occurs, in variation of
coefficients Δα and Δβ indicated in Table 1
(In temperature change of 100° C.)

| | | Amount of frequency variation in | | |
|---|---|---|---|---|
| | | temperature change of 100° C. (ppm) | | |
| | | Amount of | Amount of | |
| | | frequency | frequency | |
| | | variation by | variation by | |
| | | Δα = | Δβ = | |
| | | Δα*100 | Δβ*100*100 | ΔF |
| Comparative | Sample 1 | 27.4 | −6.4 | 21.0 |
| Example 1 | Sample 2 | 23.2 | −5.1 | 18.0 |
| (Amount of frequency | Sample 3 | 24.3 | −5.5 | 18.8 |
| adjustment 1,000 ppm) | | | | |
| Comparative | Sample 1 | 42.6 | −8.9 | 33.6 |
| Example 1 | Sample 2 | 44.8 | −8.8 | 36.0 |
| (Amount of frequency | Sample 3 | 45.9 | −8.3 | 37.7 |
| adjustment 2,000 ppm) | | | | |
| Working Example | Sample 1 | 6.2 | −8.1 | 2.0 |
| (Amount of frequency | Sample 2 | 7.2 | −9.3 | 2.1 |
| adjustment 1,000 ppm) | Sample 3 | 7.0 | −9.4 | 2.5 |
| Working Example | Sample 1 | 8.8 | −16.0 | 7.2 |
| (Amount of frequency | Sample 2 | 9.6 | −12.2 | 2.5 |
| adjustment 2,000 ppm) | Sample 3 | 9.2 | −11.7 | 2.6 |
| Comparative | Sample 1 | −0.9 | −12.3 | 13.1 |
| Example 2 | Sample 2 | −6.5 | −15.5 | 22.1 |
| (Amount of frequency | Sample 3 | −4.4 | −7.3 | 11.6 |
| adjustment 1,000 ppm) | | | | |
| Comparative | Sample 1 | −3.9 | −25.4 | 29.3 |
| Example 2 | Sample 2 | −14.3 | −13.9 | 28.3 |
| (Amount of frequency | Sample 3 | −14.4 | −5.0 | 19.4 |
| adjustment 2,000 ppm) | | | | |

According to another aspect of this disclosure, a frequency adjustment method adjusts a frequency of a piezoelectric resonator that vibrates by a coupling of a width-longitudinal mode and a length-longitudinal mode. The piezoelectric resonator includes: a first vibrator; a second vibrator connecting to one of two ends positioned along a vibration direction of the width-longitudinal mode in the first vibrator; a third vibrator connecting to another of the two ends in the first vibrator; and a supporting portion connected to two ends positioned along a vibration direction of the length-longitudinal mode in the first vibrator. When the second vibrator is divided to be defined as a first region, a second region, and a third region from the first vibrator side along the vibration direction of the width-longitudinal mode, and the third vibrator is divided to be defined as a first region, a second region, and a third region from the first vibrator side along the vibration direction of the width-longitudinal mode, the frequency adjustment method is performed by any one of methods (a) to (c) described below.

(a) The frequency adjustment method is performed by reducing mass of or adding mass to the first region in each of the second vibrator and the third vibrator.

(b) The frequency adjustment method is performed by reducing mass of or adding mass to the third region in each of the second vibrator and the third vibrator.

(c) The frequency adjustment method is performed by reducing mass of or adding mass to the first region and the third region in each of the second vibrator and the third vibrator.

In these methods, the method (c) preferably enables taking more amount of the frequency adjustment.

For implementing the disclosure of the frequency adjustment method, an amount of frequency variation Δf relative to an environmental temperature change of the piezoelectric resonator is approximated with a below-described a formula (1) or a formula (2).

It is preferred that the mass reduction region or the mass addition region be selected such that an absolute value of a difference between β (t−to) (t−to) and α (t−to) in the below-described formula (1) or formula (2) becomes equal to or less than a predetermined amount.

Here, the predetermined amount is any value that is selected corresponding to a specification required to the piezoelectric resonator. Considering a practical use, it is preferred that the predetermined amount be, for example, 30 ppm, preferably 15 ppm, and more preferably 10 ppm.

Δf=β(t−to)(t−to)+α(t−to)+C (1)

Δf=γ(t−to)(t−to)(t−to)+β(t−to)(t−to)+α(t−to)+C (2)

Here, in the formula (1) and the formula (2), α, β, and γ are coefficients, C is a constant, t is an environmental temperature, and to is any reference temperature.

Further, for implementing the disclosure of the frequency adjustment method, it is preferred that the first to third regions be, typically, regions where the vibrator, to which the first to third regions belong, is divided into three equal parts along the vibration direction of the width-longitudinal mode. Three equal parts mean including characteristically equal regions, and, for example, dimensions in a range from 0.9 to 1.1, which are dimensions of three equal pacts, are also included.

For implementing the disclosure of the frequency adjustment method, when the dimension along the vibration direction of the length-longitudinal mode in the first and third regions is expressed as M (see FIGS. 3A and 3B), it is preferred that the mass reduction region or the mass addition region in the first and the third regions be the regions that have a dimension from 0.7M (see FIGS. 5A and 5B) to M centered at the position of M/2 (see FIGS. 3A and 3B) the respective first and third regions. This fulfills the predetermined amount specified by using the second-order term and the first-order term of the above-described formula (1).

With the disclosure of the piezoelectric resonator according to the present application, the piezoelectric resonator includes: a first vibrator; a second vibrator connecting to one of two ends positioned along a vibration direction of the width-longitudinal mode in the first vibrator; a third vibrator connecting to another of the two ends in the first vibrator, and a supporting portion connected to two ends positioned along a vibration direction of the length-longitudinal mode in the first vibrator. The second vibrator is set to a first region, a second region, and a third region from the first vibrator side along the vibration direction of the width-longitudinal mode, and the third vibrator is set to a first region, a second region, and a third region from the first vibrator side along the vibration direction of the width-longitudinal mode. Only total four regions of the first region and the third region in each of the second vibrator and the third vibrator have mass-reduction marks where the mass of the vibrators has been reduced or mass-addition marks where the mass has been added to the regions.

More specifically, it is preferred that the first to third regions be the regions where the vibrators, to which the first to third regions belong, are divided into three equal parts along the vibration direction of the width-longitudinal mode. The meaning of the three equal parts includes the range described in the frequency adjustment method. Further, it is preferred that the mass-reduction mark or the mass-addition mark be in the regions that have a dimension from 0.7M (see FIGS. 5A and 5B) to M centered at the position of M/2 (see FIGS. 3A and 3B) in the first and third regions when the dimension along the vibration direction of the length-longitudinal mode in the first regions and the third regions is expressed as M (see FIGS. 3A and 3B).

The piezoelectric resonator according to this disclosure is typically a piezoelectric resonator where, what is called, a Y-cut plate of a crystal is rotated in a range from +40 to 55 degrees around the X-axis of the crystal, and is further rotated in the range from 40 to 50 degrees inside the surface. A typical method for reducing mass includes, for example, a method of ion milling or similar method that removes an excitation electrode provided for the piezoelectric resonator.

With the frequency adjustment method of the piezoelectric resonator and the piezoelectric resonator according to the disclosure, reducing mass or adding mass of the predetermined regions ensures reducing the degree of degradation of the predetermined relationship between the width-longitudinal mode and the length-longitudinal mode of the piezoelectric resonator. Therefore, this prevents the frequency versus temperature characteristic from degrading caused by performance of the frequency adjustment of the piezoelectric resonator.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A frequency adjustment method for a piezoelectric resonator vibrating by a coupling of a width-longitudinal mode and a length-longitudinal mode, wherein
the piezoelectric resonator includes:
a first vibrator;
a second vibrator connecting to one of two ends positioned along a vibration direction of the width-longitudinal mode in the first vibrator;
a third vibrator connecting to another of the two ends in the first vibrator; and
a supporting portion connected to two ends positioned along a vibration direction of the length-longitudinal mode in the first vibrator, wherein
the frequency adjustment method comprises:
setting the second vibrator to a first region, a second region, and a third region from the first vibrator side along the vibration direction of the width-longitudinal mode;
setting the third vibrator to a first region, a second region, and a third region from the first vibrator side along the vibration direction of the width-longitudinal mode; and
performing the frequency adjustment by reducing or adding a mass of at least one of the first region and the third region in each of the second vibrator and the third vibrator.

2. The frequency adjustment method according to claim 1, wherein
the frequency adjustment is performed by reducing or adding the mass of the first region in each of the second vibrator and the third vibrator.

3. The frequency adjustment method according to claim 1, wherein
the frequency adjustment is performed by reducing or adding the mass of the third region in each of the second vibrator and the third vibrator.

4. The frequency adjustment method according to claim 1, wherein
the frequency adjustment is performed by reducing or adding the mass of the first region and the mass of the third region in each of the second vibrator and the third vibrator.

5. The frequency adjustment method according to claim 1, wherein
the piezoelectric resonator has an amount of frequency variation Δf relative to an environmental temperature change of the piezoelectric resonator, the amount of frequency variation Δf being approximated by a formula (1) expressed below, and
the mass reduction region or the mass addition region is selected such that an absolute value of a difference between β (t−to) (t−to) and α (t−to) becomes equal to or less than a predetermined amount,
Δf=β(t−to)(t−to)+α(t−to)+C (1)
Δf=γ(t−to)(t−to)(t−to)+β(t−to)(t−to)+α(t−to)+C (2)
herein, in the formula (1) and the formula (2), α, β, and γ are coefficients, C is a constant, t is an environmental temperature, and to is any reference temperature.

6. The frequency adjustment method according to claim 1, wherein
the first region, the second region and the third region are regions where the second vibrator and the third vibrator to which the first region, the second region and the third region belong are divided into three equal parts along the vibration direction of the width-longitudinal mode.

7. The frequency adjustment method according to claim 1, wherein
the mass reduction regions or the mass addition regions of the first and third regions are the regions that have a dimension of 0.7M to M centered at a position of M/2 in each of the first region and the third region when a dimension along the vibration direction of the length-longitudinal mode in the first region and the third region is expressed as M.

8. A piezoelectric resonator vibrating by a coupling of a width-longitudinal mode and a length-longitudinal mode, the piezoelectric resonator comprising:
a first vibrator;
a second vibrator connecting to one of two ends positioned along a vibration direction of the width-longitudinal mode in the first vibrator;
a third vibrator connecting to another of the two ends in the first vibrator; and
a supporting portion connected to two ends positioned along a vibration direction of the length-longitudinal mode in the first vibrator, wherein
the second vibrator is set to a first region, a second region, and a third region from the first vibrator side along the vibration direction of the width-longitudinal mode, and the third vibrator is set to a first region, a second region, and a third region from the first vibrator side along the vibration direction of the width-longitudinal mode, and
at least one of the first region and the third region in each of the second vibrator and the third vibrator have mass-reduction marks or mass-addition marks, the mass-reduction marks are marks where masses of the second vibrator and a mass of the third vibrator are removed, and the mass-addition marks are marks where masses of the second vibrator and a mass of the third vibrator are added.

9. The piezoelectric resonator according to claim 8, wherein
the first to third regions are regions where the second vibrator and the third vibrator to which the first to third regions belong are divided into three equal parts along the vibration direction of the width-longitudinal mode.

10. The piezoelectric resonator according to claim 9, wherein
the mass-reduction marks or the mass-addition marks are present in the regions that have a dimension of 0.7M to M centered at a position of M/2 in each of the first and third regions when a dimension along the vibration direction of the length-longitudinal mode in the first and third regions is expressed as M.
